(19) United States
(12) Patent Application Publication
(10) Pub. No.: US 2017/0241018 A1
(43) Pub. Date: Aug. 24, 2017

(54) FILM DEPOSITION APPARATUS, FILM DEPOSITION METHOD AND COMPUTER READABLE MEDIUM

(71) Applicant: Tokyo Electron Limited, Tokyo (JP)

(72) Inventors: Katsuhiko OYAMA, Iwate (JP); Kiichi TAKAHASHI, Iwate (JP); Yasushi TAKEUCHI, Iwate (JP); Katsuyoshi AIKAWA, Iwate (JP)

(21) Appl. No.: 15/434,524

(22) Filed: Feb. 16, 2017

(30) Foreign Application Priority Data
Feb. 22, 2016 (JP) 2016-031062

(51) Int. Cl. C23C 16/458; C23C 16/52; C23C 16/455

(52) U.S. Cl. CPC C23C 16/4584; C23C 16/455; C23C 16/52

(57) ABSTRACT

A film deposition apparatus includes a chamber and a turntable provided in the chamber. The turntable includes a concave portion in its upper surface. A bottom portion of the concave portion has a through hole. A substrate supporting member is detachably placed on the concave portion so that a lower surface thereof is exposed from the through hole, and includes a substrate receiving portion. A drive mechanism moves up and down and rotates the turntable. A rotary unit rotatable by air is provided under the turntable. An air supply unit is provided. A controller causes the drive mechanism to rotate and move down the turntable so that the rotary unit supports the exposed lower surface of the substrate supporting member. The controller causes the air supply unit to supply air to the rotary unit so that the substrate supporting member rotates a predetermined angle relative to the turntable.

### CROSS-REFERENCE TO RELATED APPLICATIONS

This patent application is based upon and claims the priority to Japanese Patent Application No. 2016-31062 filed on Feb. 22, 2016, the entire contents of which are incorporated herein by reference.

### BACKGROUND OF THE INVENTION

1. Field of the Invention

The present invention relates to a film deposition apparatus, a film deposition and a computer-readable recording medium.

2. Description of the Related Art

Conventionally, a film deposition apparatus is known in which multiple substrates are placed on a turntable provided in a vacuum chamber in a rotational direction of the turntable, and a film is deposited on the substrate by supplying a process gas from a gas supplying part disposed along the radial direction of the turntable while rotating the turntable.

Such a film deposition apparatus may cause unbalance in the thickness of a film deposited on the substrate depending on a gas flow inside the vacuum chamber, a temperature distribution of the turntable, or the like. In particular, because the turntable performs a circular motion around its rotary shaft, the imbalance is likely to occur between sides nearer to and farther from the rotational center of the turntable.

Therefore, conventionally, as described in Japanese Laid-open Patent Application Publication No. 2010-206025, a tray is provided at the position on the turntable where a substrate is placed, and the tray is rotated by a drive unit provided outside the vacuum chamber in addition to the revolution (orbital motion) of the turntable to make the film thickness uniform.

However, according to the above technique, because the tray is structured to be rotated from the outside of the vacuum chamber, the mechanism for rotating the tray becomes complicated.

### SUMMARY OF THE INVENTION

Accordingly, embodiments of the present invention may provide a new and useful film deposition apparatus, a film deposition method and a computer readable medium that can rotate a substrate relative to a turntable by using a simple structure and can improve uniformity of a thickness of a film deposited on the substrate.

More specifically, there is provided a film deposition apparatus for sequentially supplying at least two reaction gases, which mutually react, into a chamber to deposit a film on a substrate. The film deposition apparatus includes a chamber, and a turntable provided in the chamber and configured to be rotatable. The turntable includes a concave portion in an upper surface. A bottom portion of the concave portion has a through hole. A substrate supporting member is detachably placed on the concave portion. A part of a lower surface of the substrate supporting member is exposed through the through hole of the concave portion. An upper surface of the substrate supporting member includes a receiving portion to receive the substrate thereon. A drive mechanism is configured to move up and down the turntable and rotate the turntable. A rotary unit is provided under the turntable and in the chamber and configured to be rotatable by supplying air thereto. An air supply unit is provided around the rotary unit and configured to supply air to the rotary unit to rotate the rotary unit. A controller is configured to cause the drive mechanism to rotate the turntable so that the through hole is located just above the rotary unit, and to cause the drive mechanism to move down the turntable so that the rotary unit supports the exposed lower surface of the substrate supporting member. The controller causes the air supply unit to supply air to the rotary unit while the rotary unit supports the exposed lower surface of the substrate supporting member so that the substrate supporting member rotates a predetermined angle relative to the turntable.

Additional objects and advantages of the embodiments are set forth in part in the description which follows, and in part will become obvious from the description, or may be learned by practice of the invention. The objects and advantages of the invention will be realized and attained by means of the elements and combinations particularly pointed out in the appended claims. It is to be understood that both the foregoing general description and the following detailed description are exemplary and explanatory and are not restrictive of the invention as claimed.

### BRIEF DESCRIPTION OF THE DRAWINGS

FIG. 1 is a schematic cross-sectional view of a film deposition apparatus according to an embodiment;

FIG. 2 is a schematic perspective view of a film deposition apparatus according to an embodiment;

FIG. 3 is a schematic plan view of a film deposition apparatus according to an embodiment;

FIG. 4 is a schematic perspective view of a film deposition apparatus according to an embodiment;

FIG. 5 is a schematic cross-sectional view of a film deposition apparatus according to an embodiment taken along a concentric circle of a turntable;

FIG. 6 is a schematic cross-sectional view of a separation area of a film deposition apparatus according to an embodiment;

FIG. 7 is a schematic cross-sectional view of a rotary mechanism of a wafer in a film deposition apparatus according to an embodiment;

FIG. 8 is a schematic perspective view of a rotary mechanism of a wafer in a film deposition apparatus of the embodiment;

FIG. 9 is a schematic cross-sectional view of a rotary mechanism of a wafer in a film deposition apparatus of the embodiment;

FIG. 10 is a schematic perspective view of a rotary mechanism of a wafer in a film deposition apparatus of the embodiment;

FIGS. 11A and 11B illustrate an example of a rotary unit in a film deposition apparatus according to an embodiment;

FIG. 12 is a diagram for explaining operation of a blade part of the rotary unit illustrated in FIGS. 11A and 11B;

FIGS. 13A through 13C are diagrams for explaining operation of the blade part illustrated in FIG.

FIGS. 14A and 14B are diagrams illustrating an example of an air supply part for implementing the operation of the blade part illustrated in FIGS. 13A through 13C;

FIGS. 15A and 15B illustrate another example of the rotary unit in the film deposition apparatus according to an embodiment;

FIG. 16 is a diagram for explaining the blade part of the rotary unit illustrated in FIGS. 15A and 15B;

FIGS. 17A through 17C are diagrams for explaining operation of the blade part illustrated in FIG. 16;

FIGS. 18A and 18B are diagrams illustrating an example of an air supply part for implementing the operation of the blade part illustrated in FIGS. 17A through 17C;

FIG. 19 is a flowchart illustrating an example of a film deposition method according to an embodiment;

FIGS. 20A and 20B are first process charts of a film deposition method according to an embodiment;

FIGS. 21A and 21B are second process charts of a film deposition method according to an embodiment;

FIGS. 22A and 22B are third process charts of a film deposition method according to an embodiment;

FIGS. 23A and 23B are fourth process charts of a film deposition method according to an embodiment;

FIGS. 24A and 24B are fifth process charts of a film deposition method according to an embodiment; and

FIGS. 25A and 25B are sixth process charts of a film deposition method according to an embodiment.

### DETAILED DESCRIPTION OF EMBODIMENTS

Embodiments of the present disclosure are described below with reference to accompanying drawings. Through all figures illustrating the embodiments, the same references symbols are used for portions having the same function, and repetitive explanations of these portions are omitted.

[Film Deposition Apparatus]

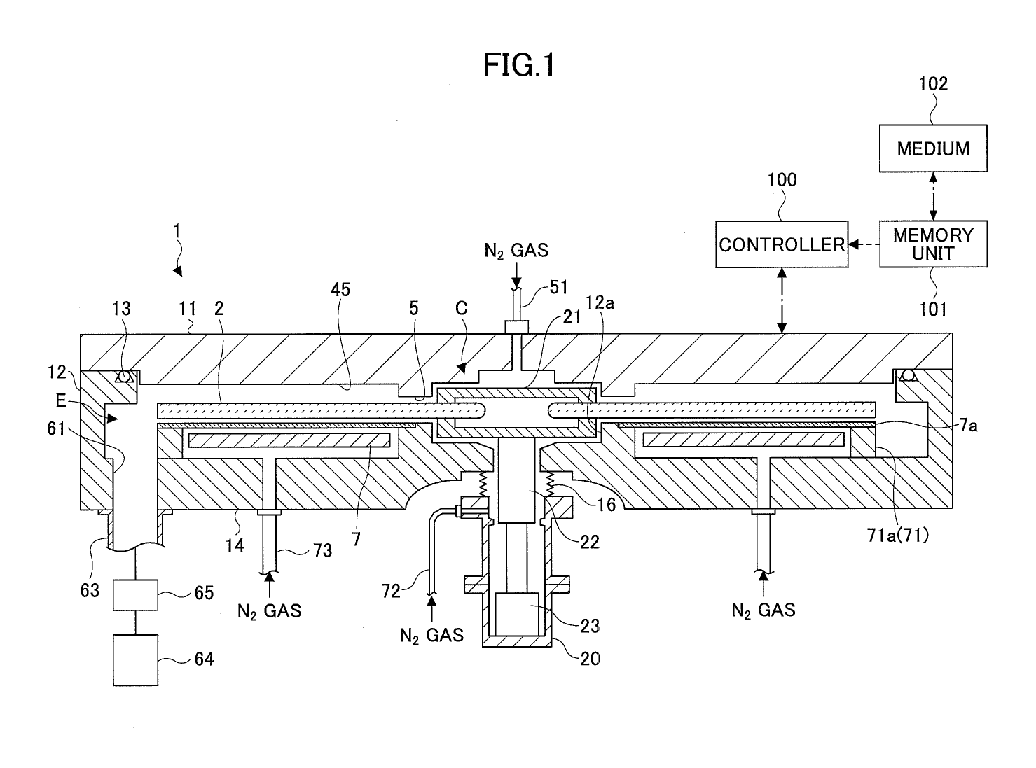

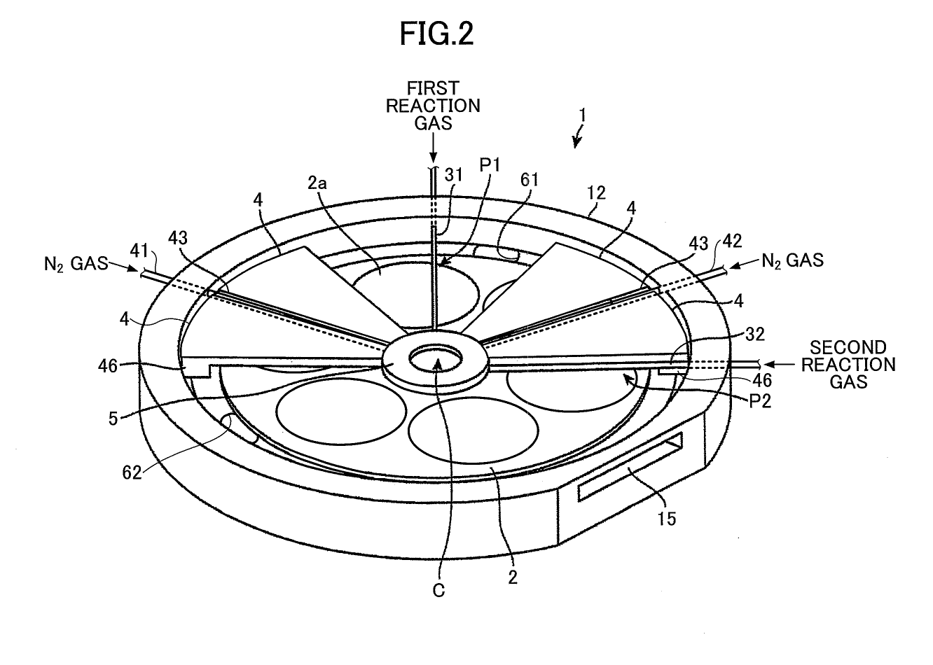

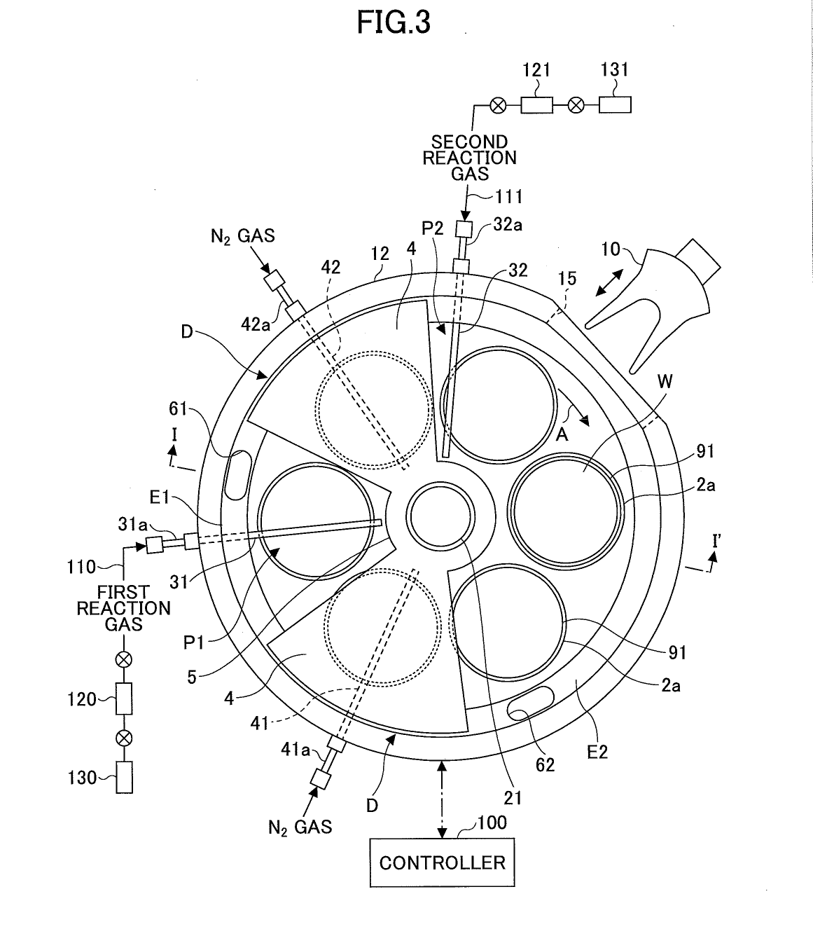

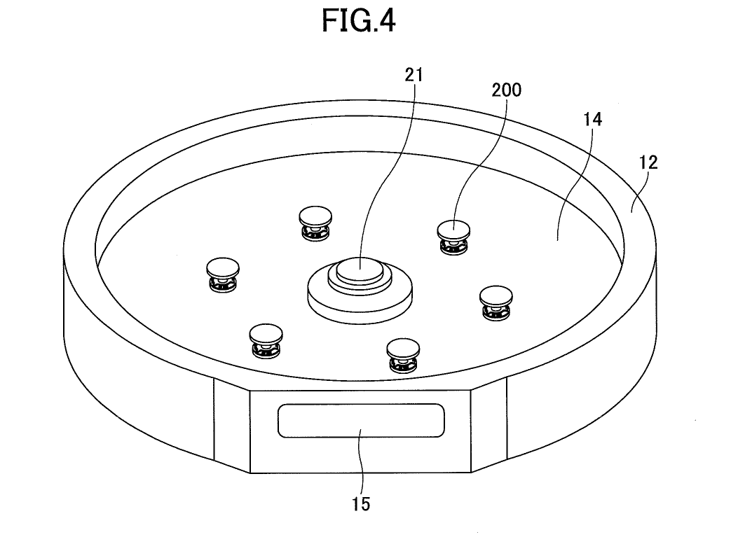

Referring to FIGS. 1 through 6, the film deposition apparatus according to an embodiment is described below. FIG. 1 is a schematic cross-sectional view of a film deposition apparatus according to the embodiment. FIGS. 2 through 4 are schematic perspective views of the film deposition apparatus according to the embodiment. FIG. 3 is a schematic plan view of the film deposition apparatus according to the embodiment. For convenience of explanation, a ceiling plate is omitted from illustration in FIGS. 2 and 3. In FIG. 4, illustration of a ceiling plate, a turntable, a covering member, a heater unit, a nozzle and the like is omitted for convenience of explanation.

Referring to FIGS. 1 through 3, the film deposition apparatus according to the embodiment includes a vacuum chamber 1 having a substantially circular shape in a plan view and a flattened shape in a side view, and a turntable 2 having its rotational center coincided with the center of the vacuum chamber 1. The vacuum chamber 1 is a process chamber for depositing a film on the upper surface of a wafer that is accommodated in the vacuum chamber 1. The vacuum chamber 1 includes a chamber body 12 having a cylindrical shape with a bottom, and a ceiling plate 11, which is detachably provided on the upper surface of the chamber body 12 through a sealing member 13 such as an O-ring to hermetically seal the chamber 1.

The turntable 2 is accommodated in the vacuum chamber 1 and configured to be rotatable. The turntable 2 is fixed to a core portion 21 formed in a cylindrical shape at the center portion of the turntable 2. This core portion 21 is fixed to the upper end of a rotary shaft 22 extending in the vertical direction. The rotary shaft 22 penetrates through a bottom portion 14 of the vacuum chamber 1. The lower end of the rotary shaft 22 is attached to a drive unit 23. The drive unit 23 includes a pressure air cylinder and a stepping motor to lift up and down the rotary shaft 22 and therefore lift up and down the turntable 2. The drive unit 23 causes the rotary shaft 22 to rotate about a vertical axis to rotate the turntable 2. The rotary shaft 22 and the drive unit 23 are accommodated in a cylindrical case body 20 whose upper surface is opened. A flange portion provided on the upper surface of the case body 20 is hermetically attached to the lower surface of the bottom portion 14 of the vacuum chamber 1 to maintain a gastight state between the inner atmosphere and the outer atmosphere of the case body 20. When the turntable 2 moves up and down, a bellows 16 contracts and expands in response to the rise and fall of the turntable 2. Thus, the gastight state between the inner atmosphere and the outer atmosphere of the case body 20 can be maintained. The bellows 16 and the drive unit 23 are an example of a drive mechanism.

Referring to FIGS. 2 and 3, multiple circular concave portions 2a (six in the drawings) are formed along the rotational direction (the circumferential direction) of the turntable 2. As illustrated in FIG. 3, the concave portion 2a includes a substrate supporting member 91 for placing a semiconductor wafer (hereinafter, referred to as a “wafer W”) that is a substrate thereon. More specifically, in the example of FIGS. 2 and 3, six substrate supporting members 91 are provided on the turntable 2 in a circle. FIG. 3 illustrates a state where the wafer W is mounted only one substrate supporting member 91 for convenience.

As illustrated in FIG. 4, multiple rotary units 200 are provided under the turntable 2 at positions covered by the substrate supporting members 91 when the substrate supporting members 91 stops at predetermined rotational positions as seen in a top plan view. In other words, the multiple rotary units 200 are provided at positions where a circle passing through the centers of the multiple rotary units 200 coincides with a circle passing through the centers of the multiple substrate supporting members 91. The rotary units 200 are units to rotate the wafers W relative to the turntable 2, and are attached to the upper surface of the bottom portion 13 of the vacuum chamber 1. Here, details of the rotary units 200 are described later.

As illustrated in FIGS. 2 and 3, reaction gas nozzles 31 and 32 and separation gas nozzles 41 and 42, which are made of, for example, quartz, are arranged above the turntable 2 while interposing gaps in the circumferential direction of the chamber 1 (the rotational direction of the turntable 2 along an arrow A in FIG. 3). In FIGS. 2 and 3, the separation gas nozzle 41, the reaction gas nozzle 31, the separation gas nozzle 42, and the reaction gas nozzle 32 are arranged in this order in the clockwise direction (the rotational direction of the turntable 2) from a transfer opening 15 described later. These nozzles 31, 32, 41, and 42 are attached to the chamber body 12 by fixing gas introducing ports 31a, 32a, 41a, and 42a (see FIG. 3), which are base portions of the nozzles 31, 32, 41, and 42, respectively, to the outer peripheral wall of the vacuum chamber 1 so as to horizontally extend along a radial direction of the chamber body 12. Thus, these nozzles 31, 32, 41, and 42 are introduced inside the vacuum. chamber 1 from the outer peripheral wall of the vacuum chamber 12.

In the present embodiment, as illustrated in FIG. 3, the reaction gas nozzle 31 is connected to a supplying source 130 for supplying the first reaction gas through a pipe 110, a flow rate controller 120, or the like. The reaction gas nozzle 32 is connected to a supplying source 131 for supplying the second reaction gas through a pipe 111, a flow rate controller 121, or the like. The separation gas nozzles 41 and 42 are connected to a supplying source (not illustrated) for supplying a separation gas through a pipe, a flow rate control valve, or the like (not illustrated). The separation gas may be an inert gas such as a noble gas of helium (He), Argon (Ar) or the like or nitrogen (N₂) gas. In the present embodiment, an example of using N₂ gas is described.

Multiple gas ejection holes 35 opening toward the turntable 2 are arranged in the reaction gas nozzles 31 and 32 along the longitudinal directions of the reaction gas nozzles 31 and 32 at an interval of, for example, 10 mm. An area under the reaction gas nozzle 31 is a first process area P1 for causing the first reaction gas to adsorb on the wafer W. An area under the reaction gas nozzle 32 is a second process area P2 for supplying a second reaction gas reacting with the first reaction gas adsorbing on the wafer W to produce a molecular layer that is a reaction product. The molecular layer that is the reaction product forms a film to be deposited (formed).

The first reaction gas may be various gases. In general, a source gas that becomes a raw material of the film to be deposited is selected as the first reaction gas. For example, when a silicon oxide film is deposited, a silicon-containing gas such as bis(tertiary-butylaminosilane) (BTBAS) gas is selected.

The second reaction gas may be various gases as long as the second reaction gas reacts with the first reaction gas to produce a reaction product. For example, when a silicon oxide film is deposited, an oxidation gas such as ozone (O₃) gas is selected.

Referring to FIGS. 2 and 3, two convex portions 4 are provided inside the vacuum chamber 1. The convex portions 4 are attached to the lower surface of the ceiling plate 11 so as to protrude toward the turntable 2 so that the convex portions 4 and the separation gas nozzles 41 and 42 form the separating areas D. Each of the convex portions 4 has a substantially fan-like shape in a plan view with its apex cut in a circular arc shape. In this embodiment, an inner circular arc is connected to a protruding portion 5 (described later) , and an outer circular arc is arranged along an inner peripheral surface of the chamber body 12 of the vacuum chamber 1.

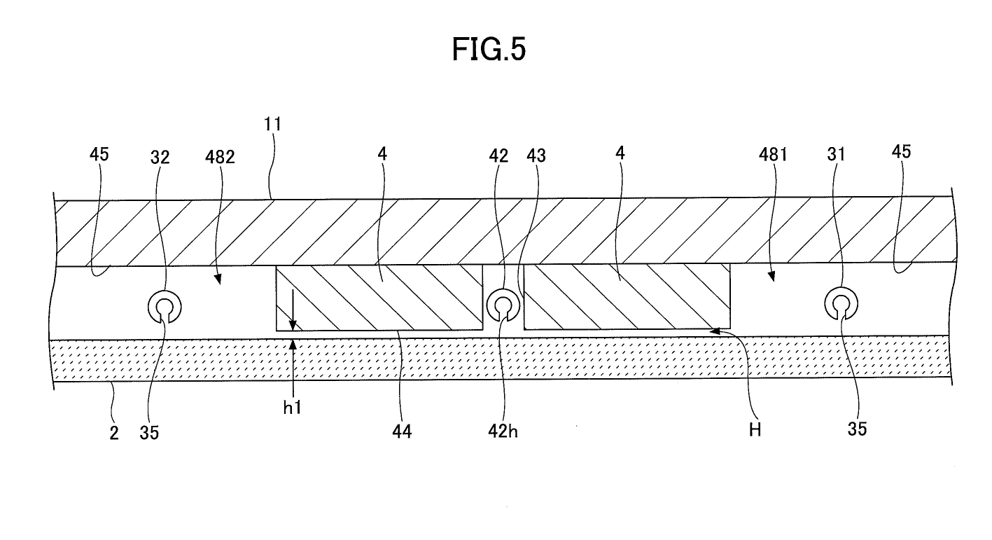

FIG. 5 is a schematic cross-sectional view of the film deposition apparatus of the embodiment taken along a concentric circle of the turntable, and illustrates a cross-section of the vacuum chamber 1 along the concentric circle of the turntable from the reaction gas nozzle 31 to the reaction gas nozzle 32. In FIG. 5, for the convenience of explanation, the substrate supporting member 91 and the wafer W are omitted from the illustration.

As illustrated in FIG. 5, a convex portion 4 is attached to the lower surface of the ceiling plate 11. Therefore, a flat and low ceiling surface 44 (a first ceiling surface) that is the lower surface of the convex portion 4 and a high ceiling surface 45 (a second ceiling surface) , which is positioned on both sides of the ceiling surface 44 and higher than the ceiling surface 44, are provided in the vacuum chamber 1. The low ceiling surface 44 is formed into a fan-like shape having an outer edge cut so as to form like a circular arc in a plan view. Furthermore, as illustrated in FIG. 5, a groove portion 43 is formed in the center of the convex portion 4 in its circumferential direction so as to extend in the radial direction. The separation gas nozzle 42 is accommodated in the groove portion 43. Another groove portion 43 is similarly formed in another convex portion 4. The separation gas nozzle 41 is accommodated in the other groove portion 43. The reaction gas nozzles 31 and 32 are provided in spaces lower than the high ceiling surface 45. The reaction gas nozzles 31 and 32 are provided in the vicinity of the wafer W and apart from the high ceiling surface 45. As illustrated in FIG. 5, the reaction gas nozzle 31 is provided in a space 481 below the high ceiling surface 45 on the right side, and the reaction gas nozzle 32 is provided in a space 482 below the high ceiling surface 45 on the left side.

The multiple gas discharge holes 42h (see FIG. 5) opening toward the turntable 2 are provided in the separation gas nozzles 41 and 42, which are accommodated in the groove portions 43 of the convex portions 4. The gas discharge holes 42h are arranged along the longitudinal directions of the separation gas nozzles 41 and 42 at an interval of, for example, 10 mm.

A separation space H, which is narrow, is formed between the ceiling surface 44 and the turntable 2. When N₂ gas is supplied from the gas discharge holes 42h of the separation gas nozzle 42, N₂ gas flows toward the spaces 481 and 482 through the separation space H. At this time, the volume of the separation space H is smaller than the volume of the spaces 481 and 482. Therefore, the pressure of the separation space H is relatively higher than the pressure in the spaces 481 and 482. In other words, the separation space H having a high pressure is formed between the spaces 481 and 482. Moreover, N₂ gas flowing into the spaces 481 and 482 from the separation space H functions as a counter flow against the first reaction gas in the first process area P1 and a counter flow against the second reaction gas in the second process area P2. Therefore, the first reaction gas from the first process area P1 and the second reaction gas from the second process area P2 are separated from each other by the separation space H. Therefore, it is possible to prevent the first reaction gas and the second reaction gas from mixing and reacting with each other inside the vacuum chamber 1.

The height h1 of the ceiling surface 44 relative to the upper surface of the turntable 2 is preferably set at a height suitable for setting the pressure in the separation space H higher than the pressure in the spaces 481 and 482 while considering the pressure inside the vacuum chamber 1 during the film deposition process, the rotational speed of the turntable 2, the supply amount of the separation gas and the like.

In the meantime, as illustrated in FIGS. 2 and 3, the protrusion portion 5 surrounding the outer periphery of the core portion 21, to which the turntable 2 is fixed, is provided under the lower surface of the ceiling plate 11. The protrusion portion 5 is continuously formed from the convex portions 4 at portions close to the rotational center of the convex portions 4. The lower surface of the protrusion portion 5 has substantially the same height as that of the ceiling surface 44.

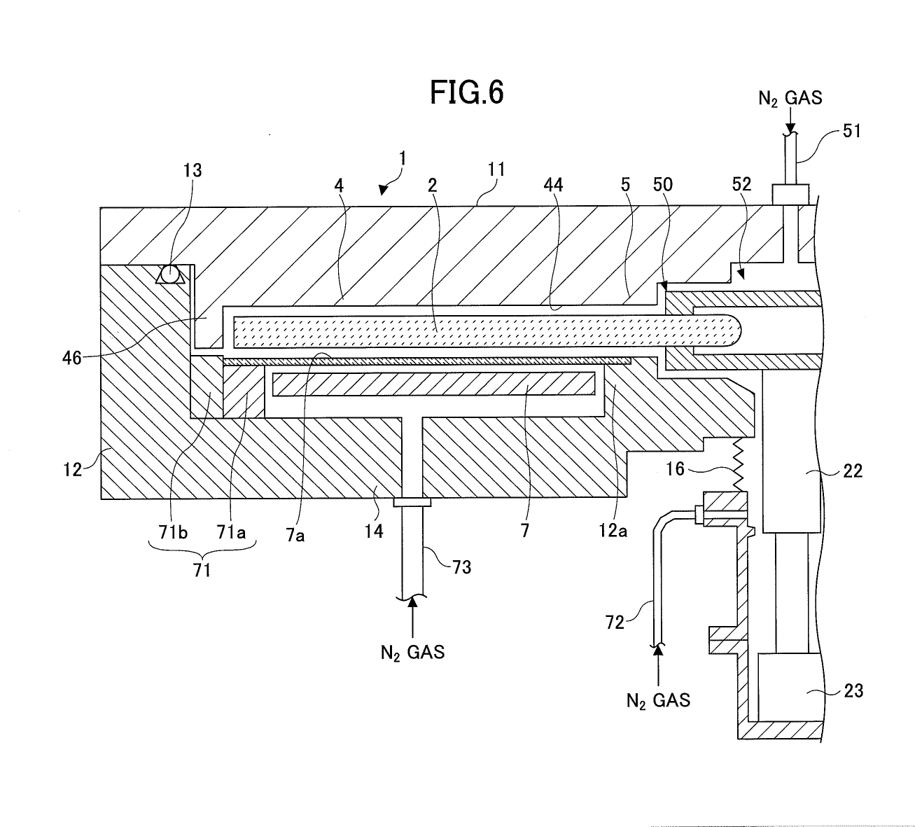

FIG. 1 is a cross-sectional view taken along a line I-I′ of FIG. 3. FIG. 1 illustrates an area where the ceiling surface 45 is provided. On the other hand, FIG. 6 is a cross-sectional view of an area where the ceiling surface 44 is provided. As illustrated in FIG. 6, a peripheral edge portion (a portion of the vacuum chamber 1 on the outer edge side) of the convex portion 4 having a fan-like shape includes a bent portion 46 bent into an L shape so as to face the outer end surface of the turntable 2. The bent portion 46 prevents reaction gases from intruding from both sides of the separating area D in a manner similar to the convex portion 4 to prevent the first reaction gas and the second reaction gas from mixing with each other. The convex portion 4 formed into the approximately fan-like shape is provided on the ceiling plate 11. Because the ceiling plate 11 is detachable from the chamber body 12, there is a small gap between the outer peripheral surface of the bent portion 46 and the chamber body 12. A gap between the inner peripheral surface of the bent portion 46 and the outer edge surface of the turntable 2 and a gap between the outer peripheral surface of the bent portion 46 and the chamber body 12 are set to have a dimension similar to, for example, that of a gap between the ceiling surface 44 and the upper surface of the turntable 2.

As illustrated in FIG. 6, the inner peripheral wall of the chamber body 12 has a vertical surface in the vicinity of the outer peripheral surface of the bent portion 46 in the separation areas D. However, as illustrated in FIG. 1, the inner peripheral wall of the chamber body 12 is recessed outward in a portion other than the separating areas D, for example, from a portion facing the outer edge surface of the turntable 2 toward the bottom portion 14. Hereinafter, for convenience of explanation, this recessed portion having a substantially rectangular shape in a cross-sectional view is referred to as an evacuation area E. Specifically, as illustrated in FIG. 3, the evacuation area in communication with the first process area P1 is referred to as a first evacuation area E1, and the evacuation area in communication with the second process area P2 is referred to as a second evacuation area E2. As illustrated in FIGS. 1 through 3, a first evacuation port 61 and a second evacuation port 62 are respectively formed in the bottom portions of the first and second evacuation areas E1 and E2. The first and second evacuation ports 61 and 62 may be connected to a vacuum pump 64 that is an evacuation unit through an evacuation pipe 63. Further, a pressure controller 65 is provided between the vacuum pump 64 and the evacuation pipe 63.

As illustrated in FIGS. 1 and 6, a heater unit 7 that is a heating means is provided in a space between the turntable 2 and the bottom portion 14 of the vacuum chamber 1. The wafer W on the turntable 2 is heated through the turntable 2 to have a temperature specified in a process recipe (for example, 200° C.). Referring to FIG. 6, a cover member 71 shaped like a ring is provided under the turntable 2 to prevent the gas from intruding into an area under the turntable 2 by separating an atmosphere from a space above the turntable 2 to the first and second evacuation areas E1 and E2 from an atmosphere in which the heater unit 7 is installed. The cover member 71 includes an inner member 71a provided extending from a position vertically corresponding to the outer edge portion of the turntable 2 to a position beyond the outer edge portion of the turntable 2, and an outer member 71b provided between the inner member 71a and the inner wall surface of the chamber 1. The outer member 71b is provided in the separation area D at a position close to the bent portion 46 below the bent portion 46 formed at the outer edge portion of the convex portion 4. The inner member 71a surrounds the heater unit 7 throughout the periphery of the heater unit 7 under the outer edge portion of the turntable 2 (and at the position below the turntable 2 and slightly beyond the outer edge portion).

A part of the bottom portion 14 closer to the rotational center than the space where the heater unit 7 is arranged has a protrusion portion 12a protruding upward toward so as to get close to the core portion 21 provided on the lower surface of the turntable 2 and in the vicinity of the center portion of the turntable 2. A narrow space is formed between the protrusion portion 12a and the core portion 21. A gap between the inner peripheral surface of a through hole for the rotary shaft 22 penetrating through the bottom portion 14 and the rotary shaft 22 is also narrow. The narrow space and the narrow gap are in communication with the inside of the casing 20. A purge gas supplying pipe 72 is provided in the case body 20 so that N₂ gas that is a purge gas is supplied into the narrow space to purge the narrow space. In the bottom portion 14 of the vacuum chamber 1, multiple purge gas supplying pipes 73 are provided to purge a space where the heater unit 7 is arranged under the heater unit 7 at intervals of a predetermined angle in the circumferential direction (only one purge gas supplying pipe 73 is illustrated in FIG. 6). Furthermore, a lid member 7a is provided between the heater unit 7 and the turntable 2. The lid member 7a that covers the space in which the heater unit 7 by extending from the inner peripheral surface of the outer member 71b (the upper surface of the inner member 71a) to the upper end portion of the protrusion portion 12a in the radial direction and extending along the circumferential direction is provided to suppress the gas from intruding into the area in which the heater unit 7 is installed. The lid member 7a is made of, for example, quartz.

A separation gas supplying pipe 51 is connected to a central portion of the ceiling plate 11 of the vacuum chamber 1. The separation gas of N₂ gas is supplied to a space 52 between the ceiling plate 11 and the core portion 21. The separation gas supplied to the space 52 is discharged toward the periphery of the turntable 2 along the upper surface of the turntable 2 on which the wafer W is placed through a narrow space 50 between the protrusion portion 5 and the turntable 2. The space 50 is maintained to have a pressure higher than those of the spaces 481 and 482 by the separation gas. Therefore, it is possible to prevent BTBAS gas supplied to the first process area P1 and O₃ gas supplied to the second process area P2 from mixing with each other after passing through the center area C. In other words, the space 50 (or the center area C) can function in a manner similar to the separation space H (or the separating area D).

As illustrated in FIGS. 2 through 4, a transfer opening 15 is formed in the side wall of the vacuum chamber 1 for transferring the wafer W that is the substrate between a transfer arm 10 provided outside and the turntable 2. The transfer opening 15 is opened and closed by a gate valve (not illustrated) . At the position facing the transfer opening 15, the wafer W is transferred between the transfer arm 10 and the substrate supporting member 91 that is the wafer receiving area on the turntable 2. To do this transfer, lift pins (not illustrated) for lifting the wafer W from the back side to transfer the wafer W by penetrating through the substrate supporting member 91 and a lifting mechanism (not illustrated) for elevating the lift pins are provided under the turntable 2 at a position where the wafer W is transferred through the transfer opening 15.

Moreover, as illustrated in FIG. 1, the film deposition apparatus according to the embodiment includes a controller 100 constituted of a computer for controlling the entire operation of the film deposition apparatus. A program to be executed by the film deposition apparatus under control of the controller 100 is stored in a memory of the controller 100. This program includes groups of steps for performing the film deposition method as described below and is stored in a recording medium 102 such as a hard disk. The program is read in a memory unit 101 by a predetermined reading device and is installed inside the controller 100.

[Rotary Mechanism]

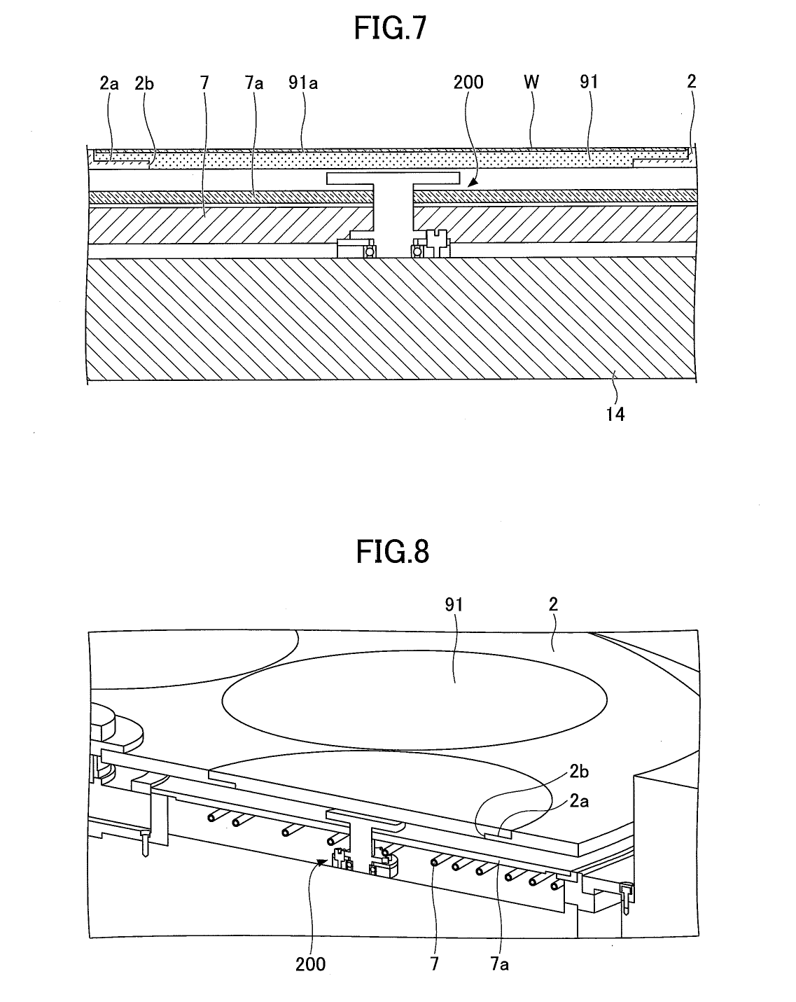

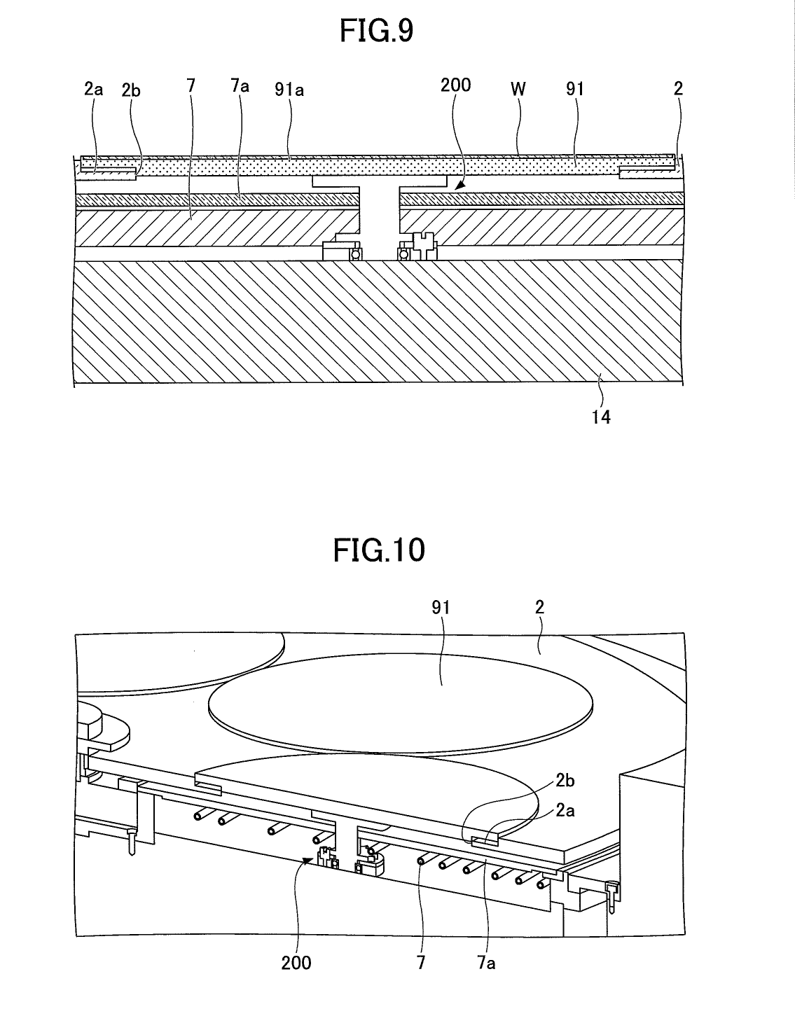

Referring to FIGS. 7 through 14, a rotary mechanism of the wafer W in the film deposition apparatus according to an embodiment is described. FIGS. 7 through 10 are schematic cross-sectional views illustrating the rotary mechanism of the wafer W in the film deposition apparatus according to the embodiment, and are enlarged views of a portion, in which a single concave portion 2a from among six concave portions 2a in FIGS. 2 and 3 is formed. FIGS. 7 and 8 illustrate the positional relationship between the turntable 2 and the rotary unit 200 when the turntable 2 is located at a position where the film is deposited on the wafer W (which is hereinafter referred to as a “film deposition position”), and are a cross-sectional view and a perspective view, respectively. Here, a position where the wafer W is transferred (i.e., carried in or carried out) (which is hereinafter referred to as a “transfer position”) may be made the same position as the position illustrated in FIGS. 7 and 8, for example. FIGS. 9 and 10 illustrate the positional relationship between the turntable 2 and the rotary unit 200 when the turntable 2 is located at a position where the wafer W is rotated (rotation) (which is hereinafter referred to as a “rotation position”) , and are a cross-sectional view and a perspective view, respectively.

As illustrated in FIGS. 7 and 8, the height of the rotary unit 200 is set at a level at which the rotary unit 200 does not contact the substrate supporting member 91 when the turntable 2 is located at a position where the turntable 2 is raised (i.e., transfer position or film deposition position) . Moreover, as illustrated in FIGS. 9 and 10, the height of the rotary unit 200 is set at a level at which the rotary unit 200 can contact and support the lower surface of the substrate supporting member 91 when the turntable 2 is located at a position where the turntable 2 is lowered (i.e., rotation position).

The turntable 2 is shaped like a disk made from a quartz plate having a thickness of about 10 mm. As illustrated in FIGS. 7 through 10, the concave portions 2a having a circular shape on which the substrate supporting member 91 is detachably mounted, is formed in the upper surface of the turntable 2. A through hole 2b having a circular shape is formed at the central part of the concave portion 2a.

The concave portion 2a has an inner diameter slightly larger (e.g., by 1 mm) than an outer diameter of the substrate supporting member 91 and a depth approximately equal to the thickness of the substrate supporting member 91. Thus, when the substrate supporting member 91 is placed on the concave portion 2a, the upper surface of the substrate supporting member 91 is at approximately the same level as the upper surface of the turntable 2 (of an area where the substrate supporting member 91 is not placed) (see FIGS. 7 and 8). If a step is formed between the upper surface of the turntable 2 and the upper surface of the substrate supporting member 91, a gas flow may be disturbed above the turntable 2 and the substrate supporting member 91, which may negatively affect uniformity of film thickness of a film deposited on the wafer W. In order to reduce the influence, the height of the upper surface of the turntable is made substantially the same as the height of the upper surface of the substrate supporting member 91, thereby preventing the gas flow from being disturbed.

The substrate supporting member 91 is provided in the concave portion 2a. The substrate supporting member 91 is formed into a disk-like shape made of, for example, a quartz plate having a thickness of 4 mm.

As illustrated in FIGS. 7 and 9, a circular concaved receiving portion 91a on which the wafer W is placed is formed in the upper surface of the substrate supporting member 91. Multiple through holes (not illustrated in the drawings) through which lift pins penetrate to support the lower surface of the wafer and to move up and down the wafer W are formed in the bottom surface of each receiving portion 91a. The substrate supporting member 91 has an inner diameter slightly larger (e.g., by 2 mm) than an outer diameter of the wafer W and a depth approximately equal to the thickness of the wafer W. Thus, when the wafer W is placed on the substrate supporting member 91, the upper surface of the wafer W is at approximately the same level as the upper surface of the substrate supporting member 91 (of an area where the substrate supporting member 91 is not placed). If a step is formed between the upper surface of the substrate supporting member 91 and the upper surface of the wafer W, a gas flow may be disturbed above the substrate supporting member 91 and the wafer W, which may negatively affect uniformity of film thickness of a film deposited on the wafer W. In order to reduce the influence, the height of the upper surface of the substrate supporting member 91 is made substantially the same as the height of the upper surface of the wafer W, thereby preventing the gas flow from being disturbed.

As illustrated in FIGS. 7 through 10, the rotary unit 200 is provided under the turntable 2 (substrate supporting member 91).

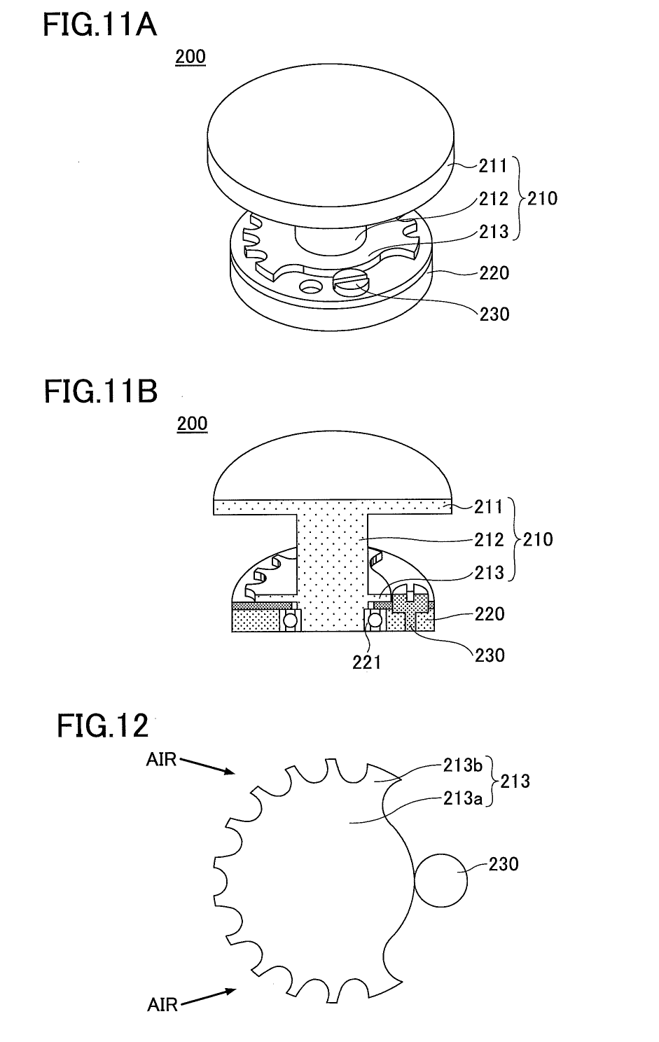

FIGS. 11A and 11B illustrate an example of a rotary unit 200 in the film deposition apparatus according to an embodiment. FIG. 11A is a perspective view of the rotary unit 200, and FIG. 11B is a perspective view of the rotary unit 200 when the rotary unit 200 is cut in the vertical direction. FIG. 12 is a diagram for explaining a blade part 213 of the rotary unit 200 illustrated in FIGS. 11A and 11B, and illustrates the blade part 213 when seen in a direction parallel to a rotary shaft of the rotary unit 200.

As illustrated in FIGS. 11A and 11B, the rotary unit 200 includes a rotary part 210, a fixed part 220, and a stopper part 230.

The rotary part 210 includes a holding part 211 for holding the substrate supporting member 91 and formed into, for example, a disk-like shape, a shaft pat 212 attached to the lower surface of the holding part 211, and the blade part 213 fixed to the shaft part 212 below the holding part 211. Here, the rotary part 210 may be formed by integral molding of the holding part 211, the shaft part 212 and the blade part 213, or may be formed by assembling the holding part 211, the shaft part 212 and the blade part 213 after formed as separate parts.

The blade part 213 is formed to be able to receive air, and rotates by receiving air supplied from an air supply part 92 described later. As illustrated in FIG. 12, for example, the blade part 213 includes a circular disk part 213a, and a plurality of projections 213b projecting outward in a radial fashion from an outer circumferential part of the circular disk part 213a. The blade part 213 includes a portion without the projection 213b in a part of the outer circumferential part of the circular disk part 213a.

As illustrated in FIGS. 11A and 11B, for example, the fixed part 220 is constituted of an annular plate member, and supports the shaft part 212 of the rotary part 210 via a bearing 221 while allowing the shaft part 212 to be rotatable. The fixed part 220 is attached to the upper surface of the bottom portion 14 of the vacuum chamber 1.

The stopper part 230 is provided on the upper surface of the fixed part 220, and stops the rotation of the rotary part 210 so as not to allow the blade part 213 to rotate a predetermined angle or more. The shape of the fixed part 220 is not limited to a specific shape, and can be formed into a variety of shapes as long as the fixed part 220 can stop the rotation of the blade part 213.

According to the rotary unit 200 having such a configuration, the substrate supporting member 91 can be rotated a predetermined angle relative to the turntable 2 by supplying air to the rotary unit 200 while the rotary unit 200 supports the lower surface of the substrate supporting member 91 when the turntable 2 is lowered.

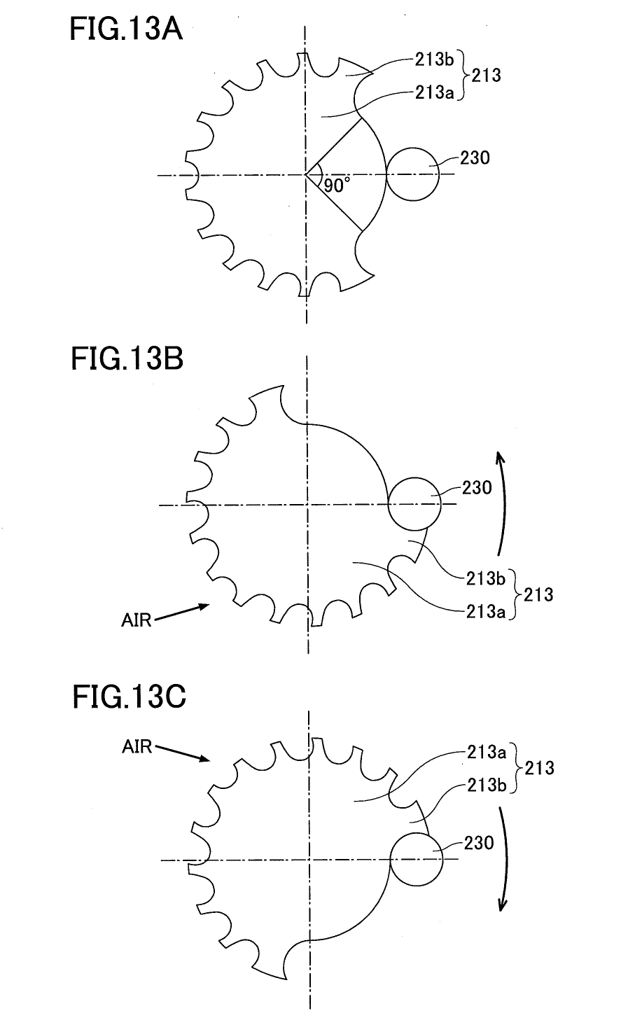

Next, referring to FIGS. 13A through 13C, operation of the rotary part 210 is described below. FIGS. 13A through 13C are diagrams for explaining the operation of the blade part 213 illustrated in FIG. 12.

The rotary part 210 is configured to be able to rotate by supplying air thereto. More specifically, the rotary part 210 rotates about the rotational axis of the shaft part 212 (see FIGS. 11A and 11B) when air is supplied to the blade part 213. For example, as illustrated in FIG. 13A, when air is not supplied to the blade part 213, the blade part 213 maintains an original state without rotating. In contrast, as illustrated in FIGS. 13B and 13C, when air is supplied to the blade part 213, the blade part 213 rotates about the rotational axis of the shaft part 212 in a counterclockwise direction (FIG. 13B) or a clockwise direction (FIG. 13C) depending on a position where air is supplied. Then, when the projection 213b contact the stopper part 230, the blade part 213 stops rotating. In FIGS. 13A through 13C, because the angle of the portion without the projection 213b among the entire circumferential part of the circular disk part 213a of the blade part 213 is 90°, a total rotational angle caused by supplying air to the blade part 213 is 90°.

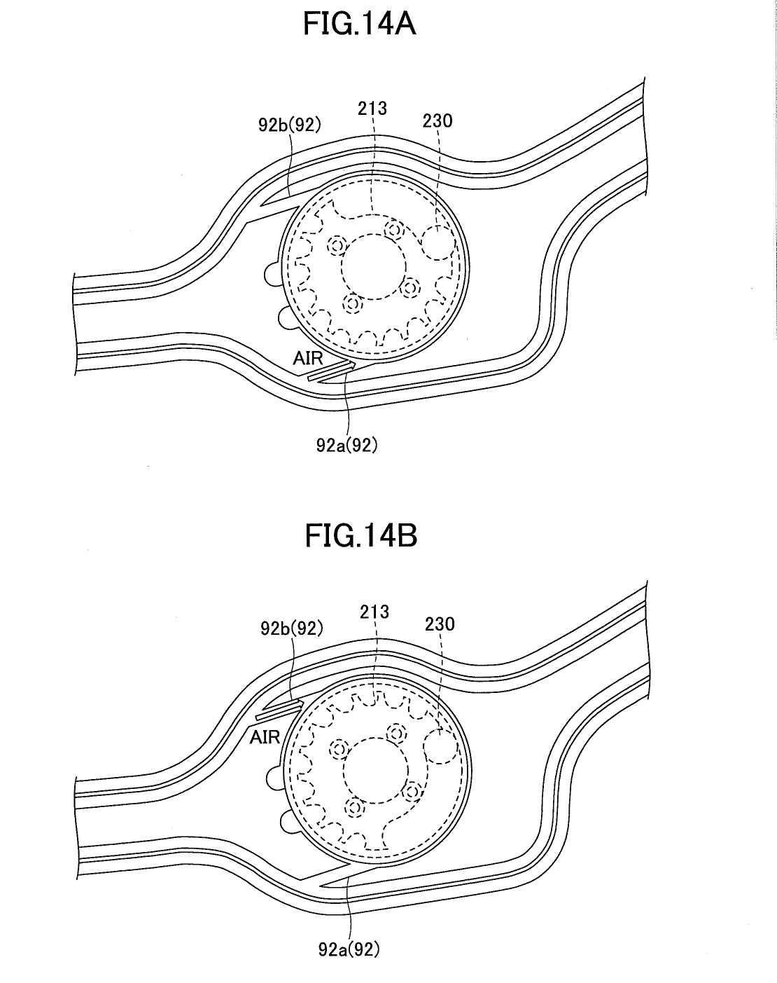

Next, referring to FIGS. 14A and 14B, the air supply part 92 for supplying air to the blade part 213 is described below. FIGS. 14A and 14B are diagrams illustrating an example of the air supply part 92 that implements the operation of the blade part 213, and illustrate the air supply part 92 when seen in a direction parallel to the rotational axis of the rotary unit 200.

As illustrated in FIGS. 14A and 14B, the air supply part 92 is provided around the rotary unit 200, and includes a first air supply part 92a and a second air supply part 92b. The first air supply part 92a supplies air to the blade part 213 so as to rotate the blade part 213 in a counterclockwise direction. The second air supply part 92b supplies air to the blade part 213 so as to rotate the blade part 213 in a clockwise direction.

As illustrated in FIG. 14A, the blade part 213 can be rotated in the counterclockwise direction by supplying air from the first air supply part 92a to the blade part 213. In contrast, as illustrated in FIG. 14B, the blade part 213 can be rotated in the clockwise direction by supplying air from the second air supply part 92b to the blade part 213. When air is supplied from the first air supply part 92a, for example, a valve (not illustrated in the drawings) provided in the first air supply part 92a is opened, while a valve (not illustrated in the drawings) provided in the second air supply part 92b is closed. In contrast, when air is supplied from the second air supply part 92b, for example, the valve provided in the first air supply part 92a is closed, while the valve provided in the second air supply part 92b is opened. Positions of the first air supply part 92a and the second air supply part 92b can be determined depending on the shape of the blade part 213. Moreover, a flow rate of air supplied from the first air supply part 92a and the second air supply part 92b is not limited to a specific value, and can be determined depending on a mass or a shape of the blade part 213.

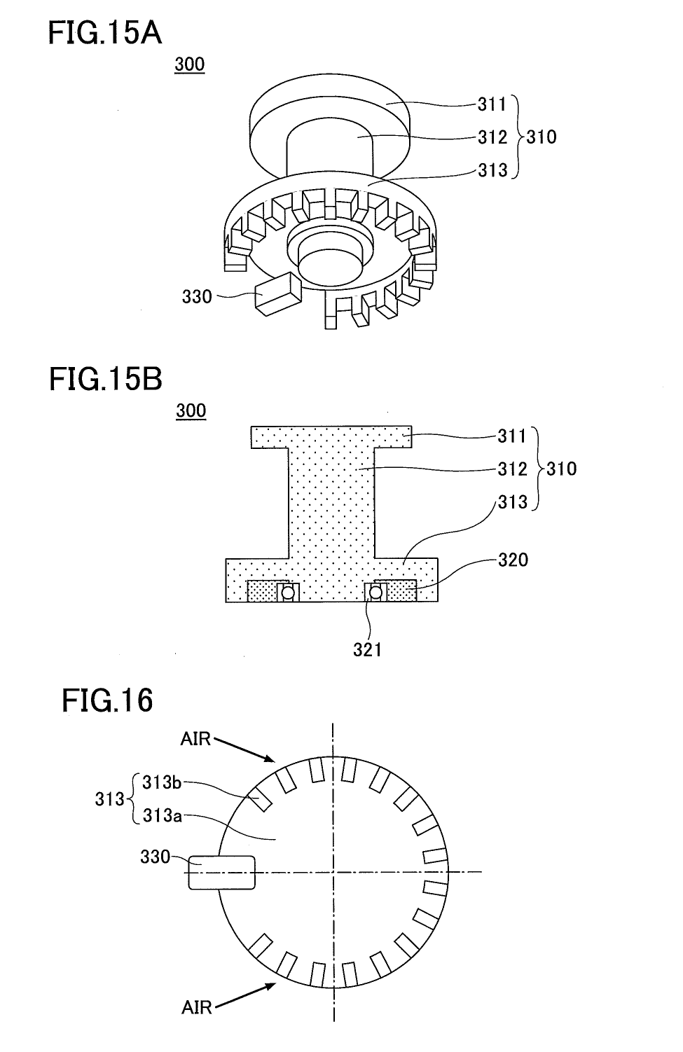

Next, referring to FIGS. 15A through 18B, another example of a rotary mechanism according to an embodiment is described below. FIGS. 15A and 15B are diagrams illustrating another example of a rotary unit 300 in a film deposition apparatus according to an embodiment. FIG. 15A is a perspective view of the rotary unit 300, and FIG. 15B is a cross-sectional view of the rotary unit 300 in FIG. 15A when cut in the vertical direction. FIG. 16 is a diagram for explaining a blade part 313 of the rotary unit 300 illustrated in FIGS . 15A and 15B, and illustrates the blade part 313 when seen in a direction parallel to the rotational axis of the rotary unit 300.

As illustrated in FIGS. 15A, 15B and 16, the rotary unit 300 includes a rotary part 310 and a fixed part 320, and a stopper part 330.

The rotary part 310 includes a holding part 311 for holding the substrate supporting member 91 and formed into, for example, a disk-like shape, a shaft pat 312 attached to the lower surface of the holding part 311, and a blade part 313 fixed to the shaft part 312 below the holding part 311. Here, the rotary part 310 may be formed by integral molding of the holding part 311, the shaft part 312 and the blade part 313, or may be formed by assembling the holding part 311, the shaft part 312 and the blade part 313 after formed as separate parts.

The blade part 313 is formed to be able to rotate by receiving air supplied from an air supply part 92 described later. As illustrated in FIGS. 15A and 16, for example, the blade part 313 includes a circular disk part 313a, and a plurality of projections 313b projecting in a direction parallel to the rotational axis of the rotary unit 300 from an outer periphery of the circular disk part 313a. The blade part 313 includes a portion without the projection 213b and recessed relative to the projection 213b, in a part of the outer periphery of the circular disk part 213a.

As illustrated in FIG. 15B, for example, the fixed part 320 is constituted of an annular plate member, and supports the shaft part 312 of the rotary part 310 via a bearing 321 while allowing the shaft part 312 to be rotatable. The fixed part 320 is attached to the upper surface of the bottom portion 14 of the vacuum chamber 1.

The stopper part 330 is provided at a position where the stopper part 330 can stop the rotation of the rotary part 310 so as not to allow the blade part 313 to rotate a predetermined angle or more. The shape of the fixed part 320 is not limited to a specific shape, and can be formed into a variety of shapes as long as the fixed part 320 can stop the rotation of the blade part 313.

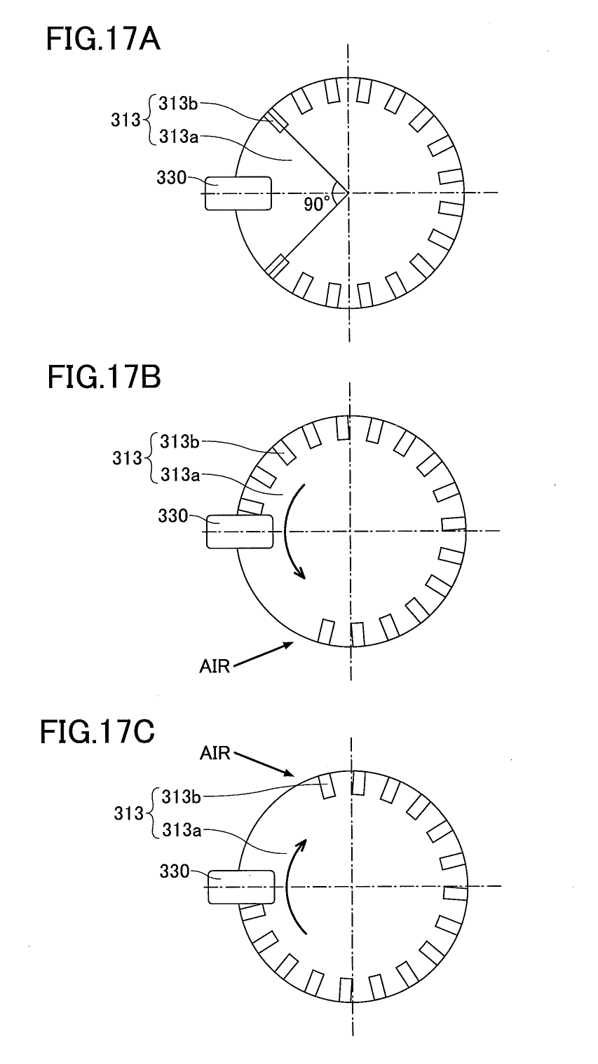

Next, referring to FIGS. 17A through 17C, operation of the rotary part 310 is described below. FIGS. 17A through 17C are diagrams for explaining the operation of the blade part 313 illustrated in FIG. 16.

The rotary part 310 is configured to be able to rotate by supplying air thereto. More specifically, the rotary part 310 rotates about the rotational axis of the shaft part 312 (see FIGS. 15A and 15B) when air is supplied to the blade part 313. For example, as illustrated in FIG. 17A, when air is not supplied to the blade part 313, the blade part 313 maintains an original state without rotating. In contrast, as illustrated in FIGS. 17B and 17C, when air is supplied to the blade part 313, the blade part 313 rotates about the rotational axis of the shaft part 312 in a counterclockwise direction (FIG. 17B) or clockwise direction (FIG. 17C) depending on a position where air is supplied. Then, when the projection 313b contact the stopper part 330, the blade part 313 stops rotating. In FIGS. 17A through 17C, because the angle of the portion without the projection 313b among the entire circumferential part of the circular disk part 313a of the blade part 313 is 90°, a total rotational angle caused by supplying air to the blade part 313 is 90°.

Furthermore, similar to the rotary unit 200 discussed above, the height of the rotary part 310 is set at a level at which the rotary part 310 does not contact the substrate supporting member 91 when the turntable 2 is located at a position where the turntable 2 is raised (i.e., transfer position or film deposition position). Moreover, similar to the rotary unit 200 discussed above, the height of the rotary part 310 is set at a level at which the rotary part 310 can contact and support the lower surface of the substrate supporting member 91 when the turntable 2 is located at a position where the turntable 2 is lowered (i. e., rotation position).

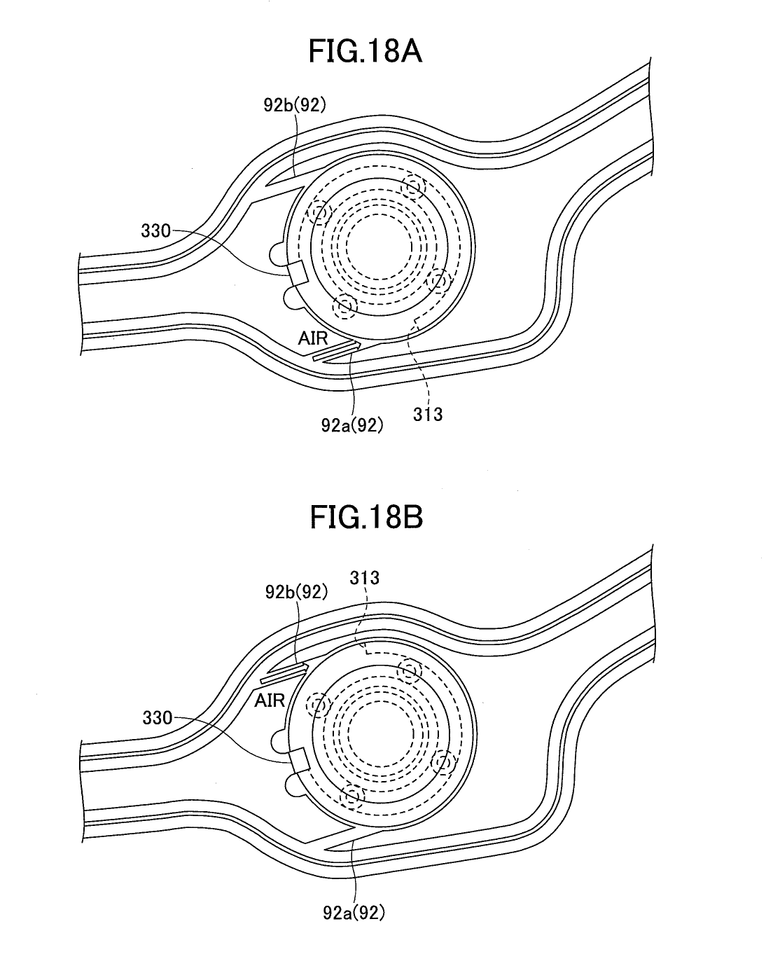

Thus, the substrate supporting member 91 can be rotated a predetermined angle relative to the turntable 2 by supplying air from an air supply part 92 to the rotary unit 300 while the rotary unit 300 supports the lower surface of the substrate supporting member 91 when the turntable 2 is lowered (see FIGS. 18A and 18B).

Next, referring to FIGS. 18A and 18B, the air supply part 92 for supplying air to the blade part 313 is described below. FIGS. 18A and 18B are diagrams illustrating an example of the air supply part 92 that implements the operation of the blade part 313, and illustrate the air supply part 92 when seen in a direction parallel to the rotational axis of the rotary unit 300.

As illustrated in FIGS. 18A and 18B, the air supply part 92 is provided around the rotary unit 300, and includes a first air supply part 92a and a second air supply part 92b. The first air supply part 92a supplies air to the blade part 313 so as to rotate the blade part 313 in a counterclockwise direction. The second air supply part 92b supplies air to the blade part 313 so as to rotate the blade part 313 in a clockwise direction.

As illustrated in FIG. 18A, the blade part 313 can be rotated in the counterclockwise direction by supplying air from the first air supply part 92a to the blade part 313. In contrast, as illustrated in FIG. 18B, the blade part 313 can be rotated in the clockwise direction by supplying air from the second air supply part 92b to the blade part 313. When air is supplied from the first air supply part 92a, for example, a valve (not illustrated in the drawings) provided in the first air supply part 92a is opened, while a valve (not illustrated in the drawings) provided in the second air supply part 92b is closed. In contrast, when air is supplied from the second air supply part 92b, for example, the valve provided in the first air supply part 92a is closed, while the valve provided in the second air supply part 92b is opened. Positions of the first air supply part 92a and the second air supply part 92b can be determined depending on the shape of the blade part 313. Moreover, a flow rate of air supplied from the first air supply part 92a and the second air supply part 92b is not limited to a specific value, and can be determined depending on a mass or a shape of the blade part 313.

[Film Deposition Method]

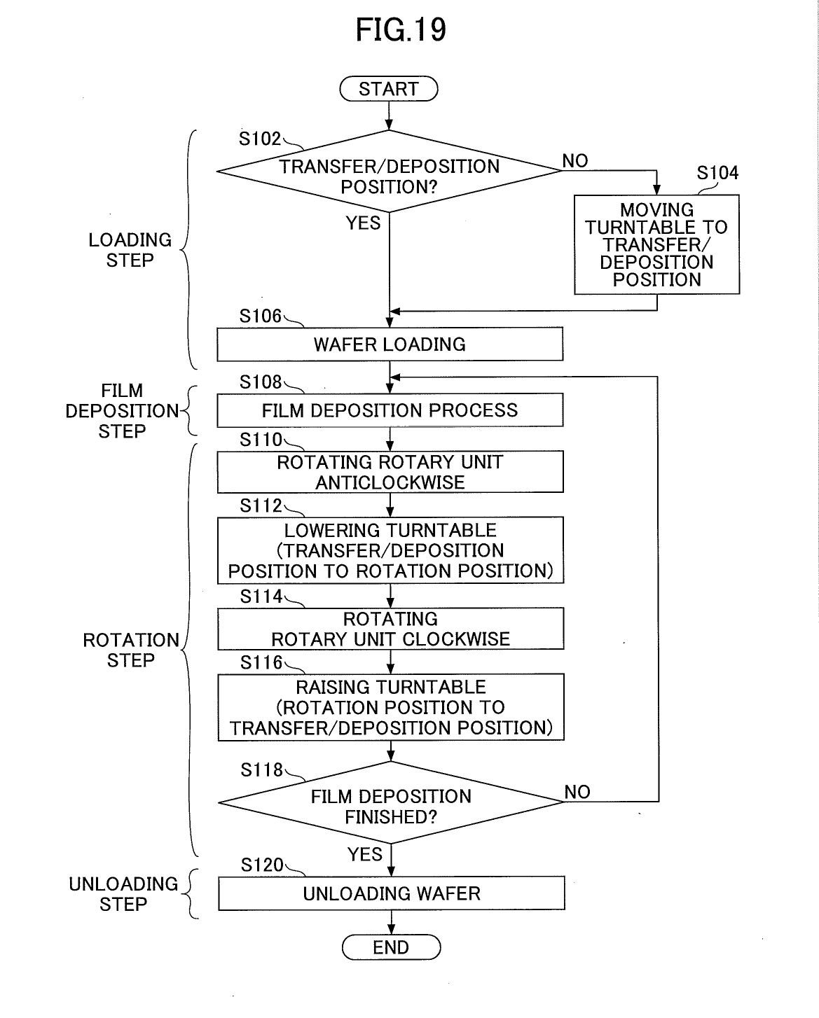

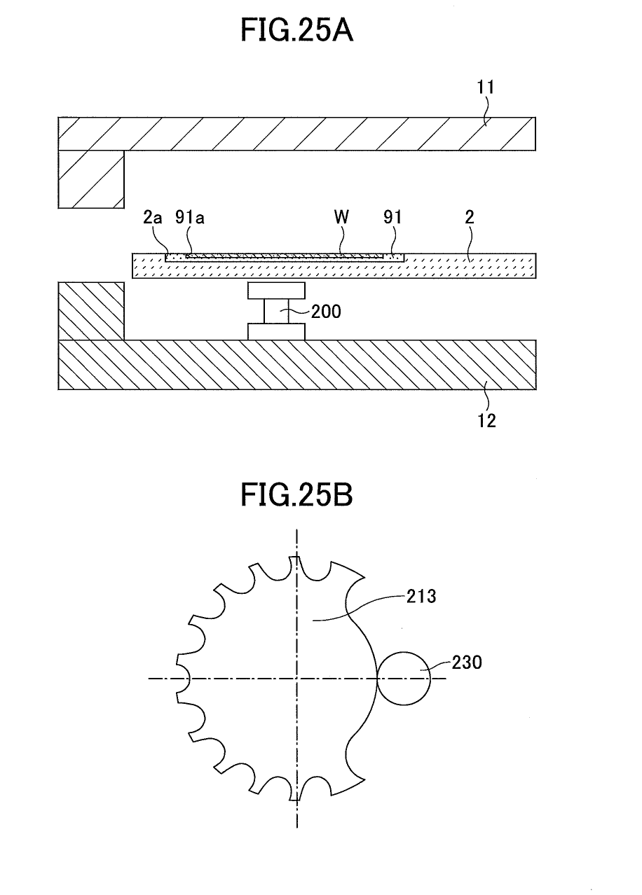

A film deposition method according to an embodiment is described below with reference to FIGS. 19 through 25B. FIG. 19 is a flowchart illustrating an example of the film deposition method according to the embodiment.

As illustrated in FIG. 19, the film deposition method according to the embodiment includes a loading step, a film deposition step, a rotation step, and an unloading step. In the film deposition method according to the embodiment, a film with a predetermined thickness is deposited on a wafer W by alternately repeating the film deposition step and the rotation step a plurality of times while intermittently rotating the wafer W relative to the turntable 2. In this manner, because the wafer W rotates a predetermined angle relative to the turntable 2 for each film deposition step, an amount of film deposition at each point of an upper surface of the wafer W can be made uniform. Moreover, the wafer W is rotated by the rotary unit 200 driven by using air in the rotation step, a drive unit for rotating the wafer W does not need to be provided outside the vacuum chamber 1. As a result, the wafer W can be rotated relative to the turntable 2 by using a simple mechanism, and uniformity of film thickness of a film deposited on the wafer W can be improved.

A method of depositing a silicon oxide film on a wafer W by using the above-mentioned film deposition apparatus is described below as an example of the film deposition method according to the embodiment.

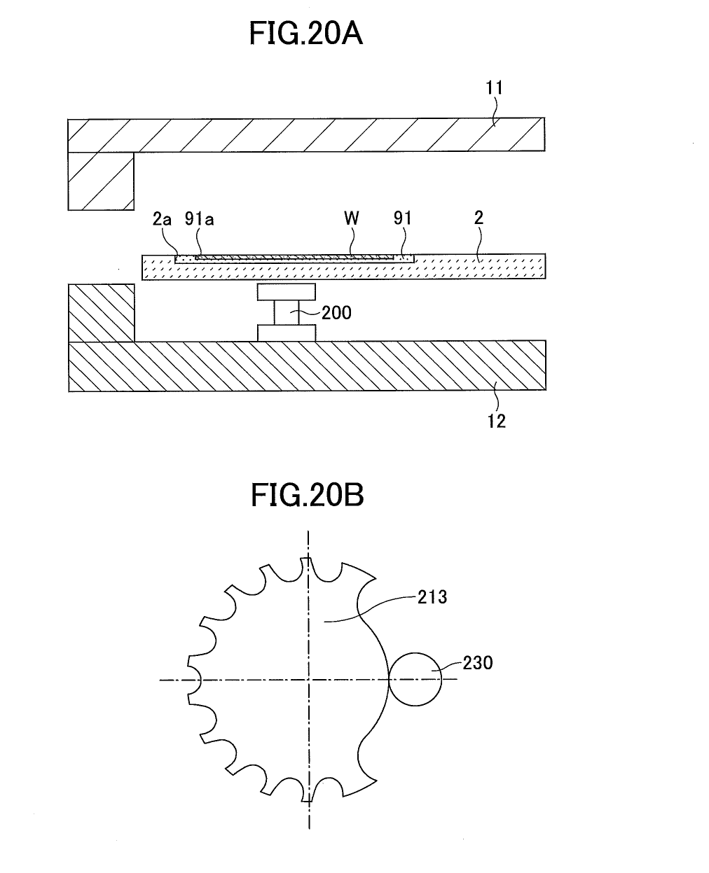

FIGS. 20A through 25B are process drawings of the film deposition method according to the embodiment. Among FIGS. 20A through 25B, FIGS. 20A, 21A, 22A, 23A, 24A and 25A are enlarged schematic cross-sectional views illustrating a portion in which a single concave portion 2a is formed from among six concave portions 2a in FIGS. 2 and 3, and FIGS. 20B, 21B, 22B, 23B, 24B and 25B are schematic plan views for explaining a blade part of the rotary unit 200.

An example in which a transfer position and a film deposition position is the same (which is also referred to as a “transfer/deposition position” hereinafter) is described below, but the transfer position and the film deposition position may be different from each other as long as a lower surface of the substrate supporting member 91 does not contact the rotary unit 200.

(Loading Step)

To begin with, the controller 100 determined whether the turntable 2 is located at a transfer/deposition position (step S102).

In step S102, when the controller 100 determines that the turntable 2 is located at the transfer/deposition position, the controller 100 controls the film deposition apparatus so as to carry a wafer W into the vacuum chamber 1 (step S106). More specifically, a gate valve (not illustrated) is opened, and as illustrated in FIG. 20A, the wafer W is transferred to a receiving portion 91a of the substrate supporting member 91 through the transfer opening 15 by s transfer arm 10 from the outside of the vacuum chamber 1. The transfer is performed by causing the lift pins (not illustrated in the drawings) to move up and down when the receiving portion 91a is stopped at a position facing the transfer opening 15 from the bottom portion 14 side of the vacuum chamber 1 via the through hole in the bottom surface of the receiving portion 91a. Such a transfer of the wafer W is performed by intermittently rotating the turntable 2 and wafers W are placed on the six receiving portion of the substrate supporting member 91. At this time, because air is not supplied to the blade part 213, as illustrated in FIG. 20B, the blade part 213 is in a state of not rotating in any direction.

In step S102, when the controller 100 determines that the turntable 2 is not located at the transfer/deposition, the controller 100 moves up and down the turntable 2 so as to move to the transfer/deposition position (step S104). After the turntable 2 moves to the transfer/deposition position, the controller 100 controls the film deposition apparatus so as to cause the wafer W to be loaded into the vacuum chamber (step S106).

(Film Deposition Step)

Subsequently, the controller 100 controls the film deposition apparatus so as to perform a film deposition process on the wafer W under predetermined film deposition conditions (step S108).

More specifically, after the wafer W is loaded into the vacuum chamber 1, the gate valve is closed and the vacuum chamber 1 is evacuated to a preset pressure by the vacuum pump 64. Next, the turntable 2 is rotated (an orbital motion for the wafers W) in a clockwise direction. The turntable 2 and the substrate supporting member 91 are previously heated to a predetermined temperature. The wafer W is heated after the wafer W is placed on the receiving portion 91a. After the wafer W is heated to the predetermined temperature, a first reaction gas (e.g., BTBAS gas) is supplied from the reaction gas nozzle 31 to the first process area P1 and a second reaction gas (e.g., O₃ gas) is supplied from the reaction gas nozzle 32 to the second process area P2. Furthermore, a separation gas (e.g., N₂ gas) is supplied from separation gas nozzles 41 and 42.

When the wafer W passes through the first process area P1, which is positioned under the reaction gas nozzle 31, BTBAS molecules adsorb to the upper surface of the wafer W. When the wafer W passes through the second process area P2, which is positioned under the reaction gas nozzle 32, O₃ molecules adsorb to the upper surface of the wafer W and the adsorbed O₃ molecules oxidize the BTBAS molecules. In other words, when the wafer W passes through the first process area P1 and the second process area P2 one time, one molecular layer of silicon oxide is deposited on the upper surface of the wafer W. Then, after the wafer W alternately passes through the first and second process areas P1 and P2 predetermined number of times by the rotation of the turntable 2, the supply of the BTBAS gas and O₃ gas is stopped, and the rotation of the turntable 2 is stopped by stopping the rotation of the rotary shaft 22.

At this time, the controller 100 causes the drive unit 23 to stop the turntable 2 at a position where the through hole 2b is located just above the rotary unit 200. As discussed above with reference to FIG. 4, each of the substrate supporting members 91 is provided to cover each of the rotary unit 200. However, because the turntable 2 is rotated in the film deposition step, if the turntable 2 is stopped at any position, the rotary units 200 may not be located under the through holes 2b but may be located under the portion between the concave portions 2a. In this case, the rotary units 200 cannot contact the substrate supporting members 91 even if the turntable 2 is moved down. To prevent this, the controller 100 causes the drive unit 23 to stop the rotation of the turntable 2 at a position where the rotary units 200 are located under the substrate supporting members 91 (i.e., through holes 2b of the concave portions 2a). Thus, the rotary units 200 can contact and support the lower surfaces of the substrate supporting members 91 exposed through the through holes 2b of the concave portions 2a when the turntable 2 is moved down.

(Rotation Step)

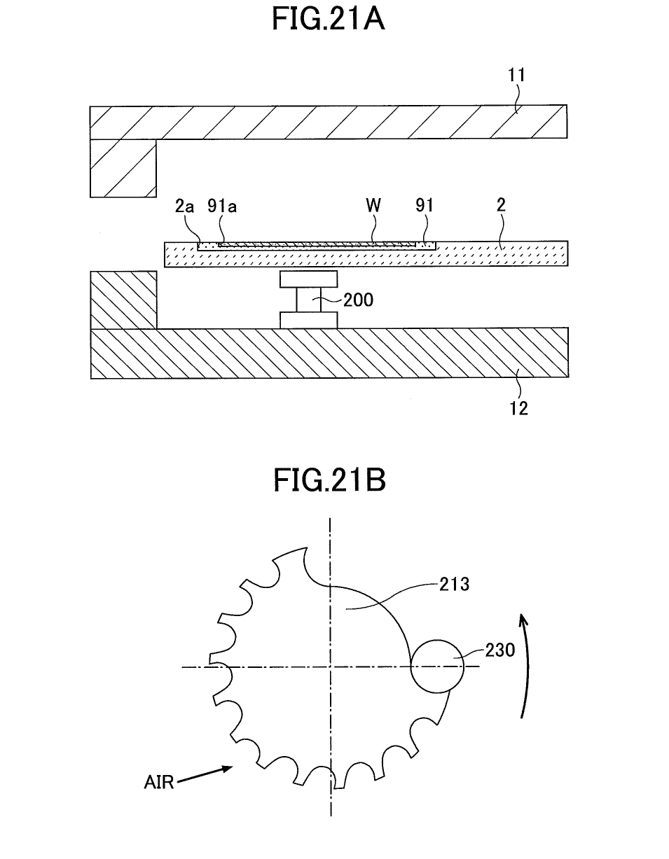

Subsequently, the controller 100 causes the rotary unit 200 to rotate in a counterclockwise direction (first rotational direction) (step S110). More specifically, as illustrated in FIG. 21B, the controller 100 causes the first air supply part 92a to supply air to the blade part 213 so that the blade part 213 rotates in the counterclockwise direction. At this time, as illustrated in FIG. 21A, because the turntable 2 is located at the transfer/deposition position, the rotary unit 200 does not contact the lower surface of the substrate supporting member 91. Due to this, when the blade part 213 rotates in the counterclockwise direction, only the rotary unit 200 rotates in the counterclockwise direction without rotating the substrate supporting member 91.

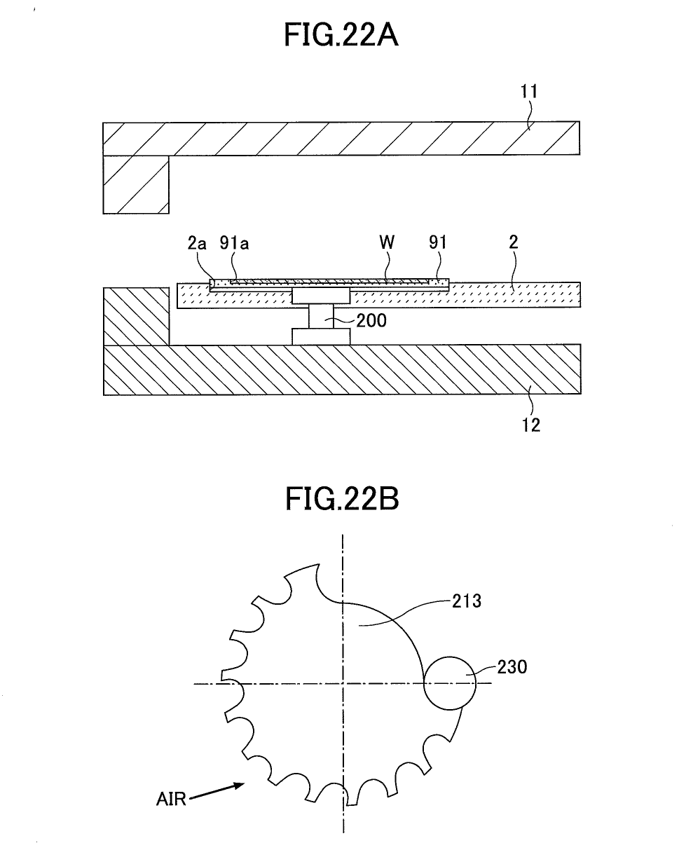

Next, the controller 100 causes the turntable 2 to move down, and to move to the rotation position from the transfer/deposition position (step S112). More specifically, as illustrated in FIG. 22A, the turntable 2 is lowered so that the lower surface of the substrate supporting member 91 contact the upper surface of the rotary and that the rotary unit 200 holds the substrate supporting member 91. At this time, the substrate supporting member 91 placed on the concave portion 2a of the turntable 2 is preferably set to be slightly apart from the concave portion 2a. Moreover, as illustrated in FIG. 22B, the rotary unit 200 does not rotate because air is continued to be supplied to the blade part 213.

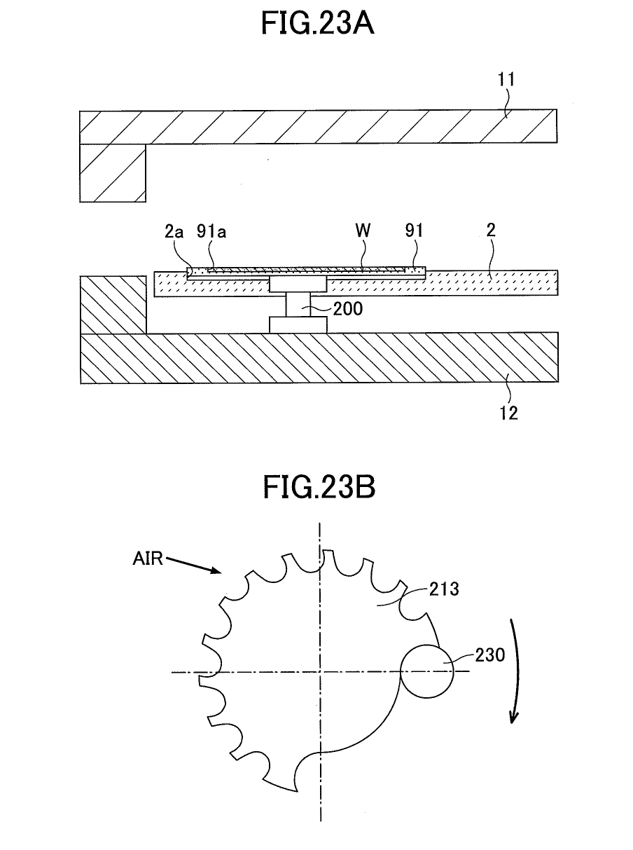

Subsequently, the controller 100 causes the rotary unit 200 to rotate in a clockwise direction (second rotational direction) (step S114) . More specifically, as illustrated in FIG. 23B, the controller 100 causes the second air supply part 92b to supply air to the blade part 213 so that the blade part 213 rotates in the counterclockwise direction. At this time, as illustrated in FIG. 23A, because the turntable 2 is located at the rotation position, the lower surface of the substrate supporting member 91 is supported by the rotary unit 200. Due to this, when the rotary unit 200 rotates a predetermined angle in the clockwise direction, only the rotary unit 200 rotates in the counterclockwise direction, the substrate supporting member 91 also rotates the predetermined angle in the clockwise direction.

Here, the predetermined angle is preferably determined so that a total rotational angle of the substrate supporting member 91 relative to the turntable 2 in the predetermined number of times of the rotation steps is equal to the integral multiple of 360° (n times) until the film thickness of the deposited film reaches a target film thickness . Thus, the wafer W rotates n times while the film with the target film thickness is deposited on the wafer W. Hence, the film thickness of a thick portion of the film and the film thickness of a thin portion of the film that are generated within the surface of the wafer W can be efficiently offset, thereby particularly improving the uniformity of film thickness of the film deposited on the wafer W.

More specifically, for example, when the rotation steps are performed 4 times until the film thickness of a deposited silicon oxide film reaches a target film thickness, the predetermined angle is preferably set at 90° (360°/4). Also, for example, when the rotation steps are performed 12 times until the film thickness of a deposited silicon oxide film reaches a target film thickness, the predetermined angle is preferably set at 60° (720°/12), 90° (1080°/12), or 120° (1440°/12).

Subsequently, the controller 100 causes the turntable 2 to move up, and to move to the transfer/deposition position from the rotation position (step S116). More specifically, as illustrated in FIG.

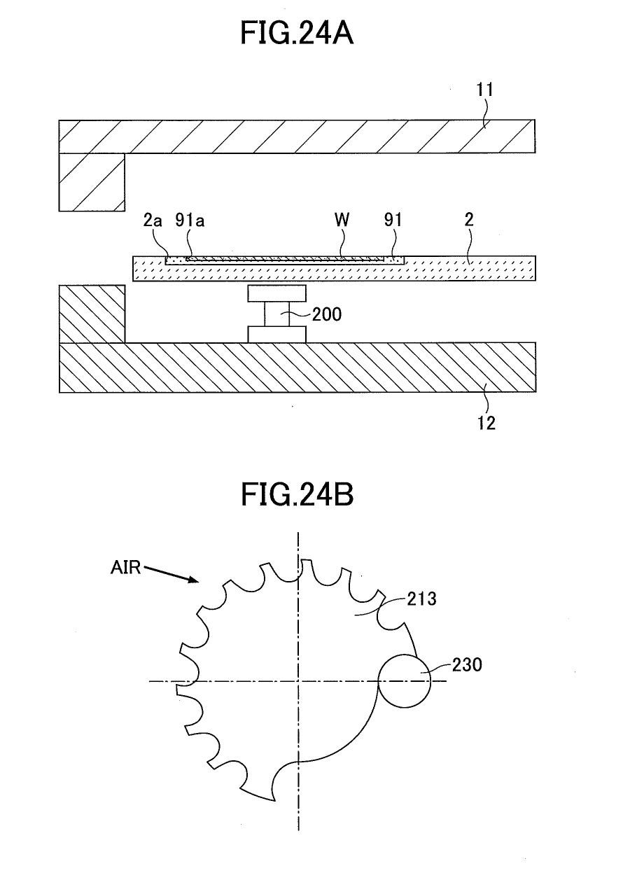

24A, the turntable 2 is raised so that the lower surface of the substrate supporting member 91 is apart from the upper surface of the rotary unit 200. Moreover, as illustrated in FIG. 24B, the rotary unit 200 does not rotate because air is kept being supplied to the blade part 213.

Next, the controller 100 determines whether the film deposition steps of the predetermined number of times are performed (step S118).

In step S118, when the controller 100 determines that the film deposition steps of the predetermined number of times are performed, the controller 100 stops the supply of air from the first air supply part 92a, and advances to step S120.

In step S118, when the controller determines that the film deposition steps of the predetermined number of times are not performed, the controller stops the supply of air from the first air supply part 92a, and returns to step S118. At this time, in the nth (n is an integral number more than or equal to one) film deposition step, a film deposition process is performed in a state where an angle of the wafer W related to the turntable 2 is rotated a predetermined angle compared to the (n−1) th film deposition step. In other words, because the wafer W rotates the predetermined angle relative to the turntable 2 for each film deposition step, the amounts of film deposition at respective points on the upper surface can be made uniform. Thus, even when a gas flow in the vacuum chamber 1 or a temperature of the turntable 2 is not uniform, the influence of the gas flow or the temperature distribution of the turntable 2 can be offset, thereby improving the uniformity of film thickness of the film deposited on the wafer W.

(Unloading Step)

The controller 100 controls the film deposition apparatus so as to unload the wafer W from the vacuum chamber 1 (step S120) . More specifically, the inside of the vacuum chamber 1 is purged, and the wafers W are sequentially unloaded from the vacuum chamber 1 by the transfer arm 10 by reversing the loading procedure.

By performing the above steps, a silicon oxide film with a predetermined film thickness is deposited on the upper surface of the wafers W.

In the film deposition method according to the embodiment, the example of rotating the rotary unit 200 in the counterclockwise direction in step S110, and rotating the rotary unit 200 in the clockwise direction in step S114, is described, but the embodiments are not limited to the example. The rotary unit 200 may be rotated in the clockwise direction in step S110, and the rotary unit 200 maybe rotated in the counterclockwise direction in step S114.

As described above, according to the embodiments, because the wafer W can be rotated a predetermined angle relative to the turntable for each film deposition step by the rotation of the rotary unit 200 using air, the amounts of film deposition at respective points on the upper surface of the wafer W can be made uniform. Due to this, the uniformity of film thickness of the film deposited on the wafer W can be improved by rotating the wafer W relative to the wafer W by using the simple mechanism.

Thus, according to the film deposition apparatus, the film deposition method and the computer readable medium, uniformity of film thickness of a film deposited on a substrate can be improved.

As discussed above, although the embodiments of the film deposition apparatus, the film deposition method and the computer readable medium have been described, the embodiments are not limited thereto, it should be understood that various changes, substitutions, and alterations could be made hereto without departing from the spirit and scope of the invention.

In the embodiments, although the deposition of the molecular layer of the silicon oxide film has been described in the embodiments, the embodiments are not limited thereto and deposition of a molecular layer of a silicon nitride film can also be performed. A nitride gas used for the deposition of the molecular layer of the silicon nitride film is, for example, ammonia (NH₃).

A source gas for depositing the molecular layer of the silicon oxide film or the molecular layer of the silicon nitride film is not limited to BTBAS. The source gas is, for example, dichlorosilane (DCS), hexachlorodisilane (HCD), tri(dimethylaminosilane) (3DMAS), and tetraethoxysilane (TEOS).

Furthermore, the film deposition apparatus of the embodiments is not limitedly used to deposit the molecular layer of the silicon oxide film or the molecular layer of the silicon nitride film. The film deposition apparatus of the embodiments can be used, to deposit a molecular layer of aluminum oxide (Al₂O₃) using trimethylaluminum (TMA) and either O₃ or oxygen plasma, a molecular layer of zirconium oxide (ZrO₂) using tetrakis(ethylmethylamino)zirconium (TEMAZ) and either O₃ or oxygen plasma, a molecular layer of hafnium oxide (HfO₂) using tetrakis(ethylmethylamino)hafnium (TEMAHf) and either O₃ or oxygen plasma, a molecular layer of strontium oxide (SrO) using strontiumbis-tetramethylheptanedionato (Sr(THD)₂) and either O₃ or oxygen plasma, a molecular layer of titanium oxide (TiO) using titaniummethylpentanedionatobis-tetramethylheptanedio nato (Ti (MPD) (THD)) and either O₃ or oxygen plasma, and so on.

All examples recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority or inferiority of the invention. Although the embodiments of the present invention have been described in detail, it should be understood that various changes, substitutions, and alterations could be made hereto without departing from the spirit and scope of the invention.

What is claimed is:

1. A film deposition apparatus for sequentially supplying at least two reaction gases, which mutually react, into a chamber to deposit a film on a substrate, the film deposition apparatus comprising:
a chamber;
a turntable provided in the chamber and configured to be rotatable, the turntable including a concave portion in an upper surface, a bottom portion of the concave portion having a through hole;
a substrate supporting member detachably placed on the concave portion, a part of a lower surface of the substrate supporting member being exposed through the through hole of the concave portion, an upper surface of the substrate supporting member including a receiving portion to receive the substrate thereon;
a drive mechanism configured to move up and down the turntable and rotate the turntable;
a rotary unit provided under the turntable and in the chamber and configured to be rotatable by supplying air thereto;
an air supply unit provided around the rotary unit and configured to supply air to the rotary unit to rotate the rotary unit; and
a controller configured to cause the drive mechanism to rotate the turntable so that the through hole is located just above the rotary unit, to cause the drive mechanism to move down the turntable so that the rotary unit supports the exposed lower surface of the substrate supporting member, and to cause the air supply unit to supply air to the rotary unit while the rotary unit supports the exposed lower surface of the substrate supporting member so that the substrate supporting member rotates a predetermined angle relative to the turntable.

2. The film deposition apparatus according to claim 1, wherein the rotary unit is attached to a bottom portion of the chamber.

3. The film deposition apparatus according to claim 1,
wherein the rotary unit comprises:
a holding part to hold the substrate supporting member;
a shaft part attached to the holding part; and
a blade part fixed to the shaft part below the holding part and configured to receive air, and
wherein the holding part, the shaft part and the blade part are rotated by supplying air to the blade part from the air supply unit.

4. The film deposition apparatus according to claim 3, wherein the rotary unit includes a stopper part configured to stop the rotation of the blade part.

5. The film deposition apparatus according to claim 3,
wherein the air supply unit comprises:
a first air supply part configured to rotate the blade part in a counterclockwise direction by supplying air to the blade part; and
a second air supply part configured to rotate the blade part in a counterclockwise direction by supplying air to the blade part.

6. The film deposition apparatus according to claim 3, wherein the blade part includes a circular disk part and a plurality of projection projecting outward in a radial fashion from an outer circumferential portion of the circular disk part.

7. The film deposition apparatus according to claim 1, wherein the blade part includes a circular disk part and a plurality of projection projecting in a direction parallel to the shaft part from a periphery of the circular disk part.

8. A film deposition method for depositing a film on a substrate by sequentially supplying at least two reaction gases, which mutually react, into a chamber, the film deposition method comprising steps of:
placing a substrate on a receiving portion provided in an upper surface of a substrate supporting member detachably placed on a concave portion formed in an upper surface of a turntable provided in a chamber and configured to be rotatable, a bottom portion of the concave portion having a through hole, a part of a lower surface of the substrate supporting member being exposed through the through hole;
depositing a film on the substrate by rotating the turntable while supplying a first reaction gas and a second reaction gas to a first process area and a second process area, respectively, the first process area and the second process area being provided apart from each other in a circumferential direction of the turntable, separation areas provided between the first process area and the second process area in the circumferential direction;
stopping the rotation of the turntable at a position where the through hole of the concave portion is just above a rotary unit provided under the turntable and in the chamber;
rotating the rotary unit in a first rotational direction by supplying air to the rotary unit;
moving down the turntable so that the rotary unit supports the exposed lower surface of the substrate supporting member;
rotating the rotary unit in a second rotational direction opposite to the first rotational direction by supplying air to the rotary unit while the rotary unit supports the exposed lower surface of the substrate supporting member, thereby rotating the substrate supporting member a predetermined angle relative to the turntable; and
moving up the turntable so that the substrate supporting member is apart from the rotary unit and placed on the concave portion of the turntable.

9. The film deposition method according to claim 8, wherein the turntable is moved down so that the substrate supporting member is apart from the concave portion of the turntable in the step of moving down the turntable.

10. The film deposition method according to claim 8,
wherein a series of the steps of stopping the rotation of the turntable, rotating the rotary unit in the first rotational direction, moving down the turntable, rotating the rotary unit in the second rotational direction and moving up the turntable forms a step rotating the substrate relative to the turntable, and
wherein the steps of depositing the film on the substrate and rotating the substrate supporting member relative to the turntable are alternately repeated a plurality of times.

11. The film deposition method according to claim 10, wherein the predetermined angle is determined so that a total rotational angle of the predetermined angle in the repeated steps of rotating the substrate supporting member relative to the turntable until the film deposited on the substrate reaches a target film thickness, is equal to an integral multiple of 360°.

12. A non-transitory computer readable medium storing a program causing a computer to perform a film deposition method by sequentially supplying at least two reaction gases, which mutually react, into a chamber to deposit a film on a substrate, the film deposition method comprising steps of:
placing a substrate on a receiving portion provided in an upper surface of a substrate supporting member detachably placed on a concave portion formed in an upper surface of a turntable provided in a chamber and a configured to be rotatable, a bottom portion of the concave portion having a through hole, a part of a lower surface of the substrate supporting member being exposed through the through hole;
depositing a film on the substrate by rotating the turntable while supplying a first reaction gas and a second reaction gas to a first process area and a second process area, respectively, the first process area and the second process area being provided apart from each other in a circumferential direction of the turntable, separation areas provided between the first process area and the second process area in the circumferential direction;
stopping the rotation of the turntable at a position where the through hole of the concave portion is just above a rotary unit provided under the turntable and in the chamber;
rotating the rotary unit in a first rotational direction by supplying air to the rotary unit;
moving down the turntable so that the rotary unit supports the exposed lower surface of the substrate supporting member;
rotating the rotary unit in a second rotational direction opposite to the first rotational direction by supplying air to the rotary unit while the rotary unit supports the exposed lower surface of the substrate supporting member, thereby rotating the substrate supporting member a predetermined angle relative to the turntable; and
moving up the turntable so that the substrate supporting member is apart from the rotary unit and placed on the concave portion of the turntable.
